(19) United States
(12) Patent Application Publication
(10) Pub. No.: US 2026/0130275 A1
(43) Pub. Date: May 7, 2026

(54) SEMICONDUCTOR PACKAGE

(71) Applicant: Samsung Electronics Co., Ltd., Suwon-si (KR)

(72) Inventor: Jaehyuk CHOI, Suwon-si (KR)

(21) Appl. No.: 19/251,543

(22) Filed: Jun. 26, 2025

(30) Foreign Application Priority Data
Nov. 6, 2024 (KR) 10-2024-0156294

(51) Int. Cl. H01L 23/31; H01L 23/00; H01L 23/29; H01L 23/522

(52) U.S. Cl. CPC H10W 74/147; H10W 20/496; H10W 74/121; H10W 74/47; H10W 90/724

(57) ABSTRACT

A semiconductor device may include a semiconductor substrate, an element layer on the semiconductor substrate, a wiring layer on the element layer, and a buffer layer provided between the semiconductor substrate and the element layer or between the element layer and the wiring layer. The buffer layer may include a first buffer layer including a plurality of first voids spaced apart from each other and a second buffer layer provided on the first buffer layer. The buffer layer includes: a first buffer layer including a plurality of first voids spaced apart from each other, and a second buffer layer provided on the first buffer layer and including a plurality of second voids spaced apart from each other, The plurality of second voids are disposed at a different height level than the plurality of first voids. The plurality of second voids include a plurality of pairs of adjacent second voids. In a plan view, each of the first voids of the buffer layer is disposed between a corresponding one of the plurality of pairs of adjacent second voids.

### CROSS-REFERENCE TO RELATED APPLICATIONS

This U.S. non-provisional patent application claims priority under 35 U.S.C. § 119 of Korean Patent Application No. 10-2024-0156294, filed on Nov. 6, 2024, the entire contents of which are hereby incorporated by reference.

### BACKGROUND

The present disclosure herein relates to a semiconductor chip and a semiconductor package.

With the development of the electronics industry, electronic components are required to have higher-level functions, higher speed, and smaller size. For example, semiconductor devices in a semiconductor package are required to have higher reliability, higher speed, and/or more functions. In order to satisfy such required characteristics, structures in a semiconductor package are more complicated and more highly integrated.

As the structures in a semiconductor package are more highly integrated, the reliability and mechanical stability of the semiconductor package may more significantly deteriorate. Therefore, researches are being carried out actively to improve the reliability and stability of a semiconductor package.

### SUMMARY

The present disclosure provides a semiconductor device with improved mechanical characteristics. The semiconductor device may be a semiconductor chip or package.

The present disclosure also provides a semiconductor chip and a semiconductor package with improved driving stability.

The purposes of the present invention are not limited to the above-mentioned purposes, and other purposes not mentioned would be clearly understood by those skilled in the art from the disclosure below.

An embodiment of the inventive concept provides a semiconductor device including: a semiconductor substrate; an element layer on the semiconductor substrate; a wiring layer on the element layer; and a buffer layer provided between the semiconductor substrate and the element layer or between the element layer and the wiring layer. The buffer layer includes: a first buffer layer including a plurality of first voids spaced apart from each other, and a second buffer layer provided on the first buffer layer and including a plurality of second voids spaced apart from each other, The plurality of second voids are disposed at a different height level than the plurality of first voids. The plurality of second voids include a plurality of pairs of adjacent second voids. In a plan view, each of the first voids of the buffer layer is disposed between a corresponding one of the plurality of pairs of adjacent second voids.

In an embodiment of the inventive concept, a semiconductor device includes: a semiconductor substrate; an element layer on the semiconductor substrate; a wiring layer on the element layer; and a first buffer layer provided between the semiconductor substrate and the element layer or between the element layer and the wiring layer, wherein the first buffer layer includes first voids and second voids spaced apart from each other. Each of the first voids is formed by a first recess extending from an upper surface of the first buffer layer towards an inside of the first buffer layer. Each of the second voids is formed by a second recess extending from a lower surface of the first buffer layer towards the inside of the first buffer layer. The plurality of second voids include a plurality of pairs of adjacent second voids. In a plan view, each of the first voids of the first buffer layer is disposed between a corresponding one of the plurality of pairs of adjacent second voids.

In an embodiment of the inventive concept, a semiconductor device includes: a package substrate; a semiconductor chip disposed on the package substrate; and a molding layer surrounding the semiconductor chip on the package substrate, wherein the semiconductor chip includes: a semiconductor substrate; a wiring layer on the semiconductor substrate; and a buffer layer interposed between the semiconductor substrate and the wiring layer, wherein the buffer layer includes: a first buffer layer including a plurality of first voids spaced apart from each other; and a second buffer layer provided on the first buffer layer, wherein the second buffer layer includes a plurality of second voids spaced apart from each other. The first voids and the second voids are alternately arranged, spaced apart from each other by a predetermined distance, and repetitively arranged in a first direction and a second direction that intersect each other in a plan view. An elastic modulus of the buffer layer is smaller than an elastic modulus of the semiconductor substrate.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view for describing a semiconductor package according to embodiments of the inventive concept;

FIG. 2 is an enlarged view of a portion, which is the portion N of FIG. 1, of a semiconductor package according to embodiments of the inventive concept;

FIG. 3 is an exploded perspective view for describing a buffer layer of a semiconductor package according to embodiments of the inventive concept;

FIG. 4 is a plan view for describing a first buffer layer of a semiconductor package according to embodiments of the inventive concept;

FIG. 5 is a plan view for describing a second buffer layer of a semiconductor package according to embodiments of the inventive concept;

FIG. 6 is a perspective view for describing a portion of a semiconductor package according to embodiments of the inventive concept;

FIGS. 7 and 8 are cross-sectional views for describing a semiconductor package according to embodiments of the inventive concept;

FIG. 9 is an enlarged view of a portion, which is the portion M of FIG. 8, of a semiconductor package according to embodiments of the inventive concept;

FIG. 10 is an enlarged view of a portion, which is the portion O of FIG. 9, of a semiconductor package according to embodiments of the inventive concept;

FIG. 11 is an enlarged view of a portion, which is the portion M of FIG. 8, of a semiconductor package according to embodiments of the inventive concept;

FIG. 12 is a flowchart illustrating a method of manufacturing a semiconductor package according to embodiments of the inventive concept;

FIG. 13 is a schematic diagram for describing the first step of FIG. 12;

FIG. 14 is a schematic diagram for describing the second step of FIG. 12; and

FIG. 15 is a schematic diagram for describing the third step of FIG. 12.

### DETAILED DESCRIPTION

Hereinafter, a semiconductor device according to the inventive concept will be described with reference to the drawings. The semiconductor device may be a semiconductor chip or package.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as ‘flat,’ ‘uniform,’ ‘same,’ ‘equal,’ ‘planar,’ ‘coplanar,’ ‘parallel,’ and ‘perpendicular,’ as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality. The term “substantially” may be used herein to emphasize this meaning.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

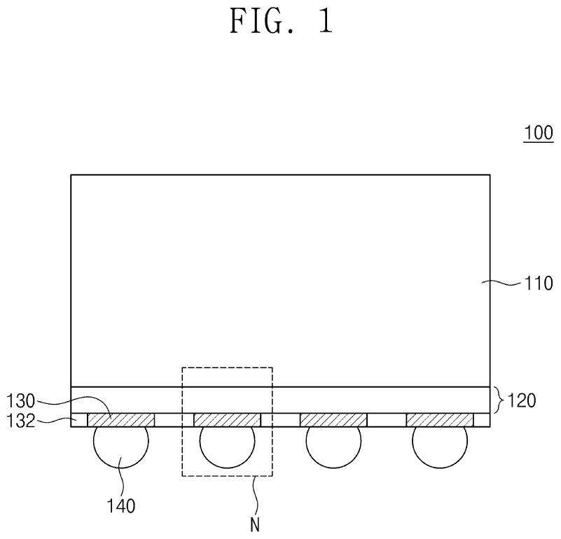

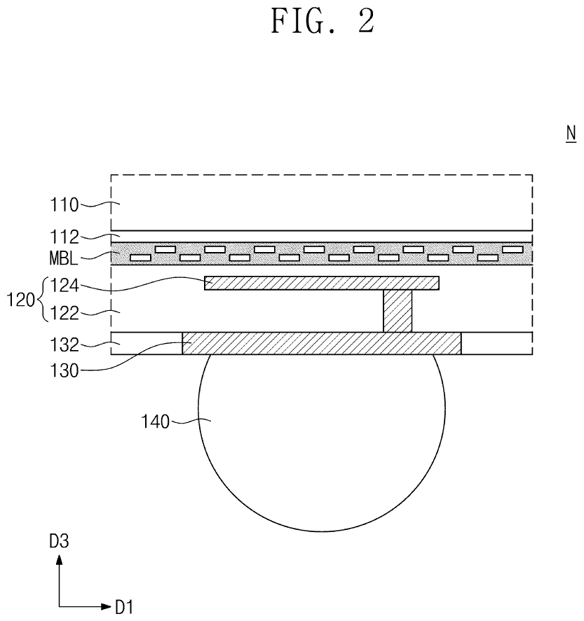

FIG. 1 is a cross-sectional view for describing a semiconductor package according to embodiments of the inventive concept. FIG. 2 is an enlarged view of a portion, which is the portion N of FIG. 1, of a semiconductor package according to embodiments of the inventive concept. Referring to FIGS. 1 and 2, a first semiconductor chip 100 may be provided. A first direction D1 and a second direction D2 may be parallel to an upper surface of the first semiconductor chip 100. The first direction D1 and the second direction D2 may be perpendicular to each other. A third direction D3 may be perpendicular to the upper surface of the first semiconductor chip 100. The first semiconductor chip 100 may include a first semiconductor substrate 110. The first semiconductor substrate 110 may include a semiconductor material. For example, the first semiconductor substrate 110 may include silicon (Si). Although not illustrated, an integrated element or integrated circuits may be provided on a lower surface of the first semiconductor substrate 110. For example, the integrated circuits may include a memory circuit or logic circuit. In some embodiments, the substrate 110 may include integrated elements or integrated circuits (or a part of integrated circuits). The integrated elements or integrated circuits may include various components such as transistors, resistors, etc., and may include conductive interconnection layers which connect the components.

A first interlayer insulating layer 112 may be provided on the lower surface of the first semiconductor substrate 110. The first interlayer insulating layer 112 may cover the lower surface of the first semiconductor substrate 110. The first interlayer insulating layer 112 may cover the integrated element or integrated circuits. An internal line connected to the integrated element or integrated circuits may be exposed on the lower surface of the first interlayer insulating layer 112. The first interlayer insulating layer 112 may include a multi-layer including at least one of silicon oxide, silicon nitride, or silicon oxynitride. However, an embodiment of the inventive concept is not limited thereto. In some embodiments, the substrate 110 may include the first interlayer insulating layer 112, and the internal line may be connected to the integrated elements or the integrated circuits. The internal line may be at least a portion of the conductive interconnection layers described above.

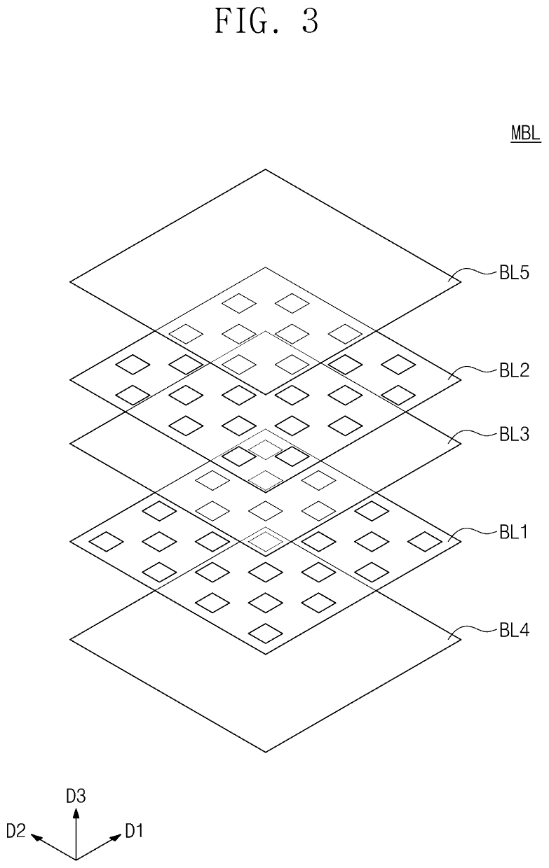

Referring to FIG. 2, a buffer layer MBL may be provided on the lower surface of the first interlayer insulating layer 112. The buffer layer MBL may cover the lower surface of the first interlayer insulating layer 112. The buffer layer MBL may have at least one layer. A thickness of the buffer layer MBL in the third direction D3 may be 5 μm to 10 μm. The buffer layer MBL may have ductility. For example, a material forming the buffer layer MBL may include a ductile material. An elastic modulus of the buffer layer MBL may be smaller than an elastic modulus of the first semiconductor substrate 110. A toughness of the buffer layer MBL may be larger than a toughness of the first semiconductor substrate 110. In FIG. 1, the buffer layer MBL and the first interlayer insulating layer 112 are not shown to enhance the understanding of the drawing. A configuration and arrangement of the buffer layer MBL will be described in more detail with reference to FIGS. 3 to 6.

A first wiring layer 120 may be provided on the lower surface of the first semiconductor substrate 110. More specifically, the first wiring layer 120 may be provided on the lower surface of the buffer layer MBL. The first wiring layer 120 may have a first insulating pattern 122 and a first wiring pattern 124 provided in the first insulating pattern 122. The first wiring pattern 124 may be connected to the internal line connected to the integrated element or the integrated circuits. For example, although not illustrated, the integrated element or the integrated circuits may be electrically connected to the first wiring pattern 124 through a connection via penetrating the buffer layer MBL.

A first chip pad 130 may be provided on the lower surface of the first semiconductor substrate 110. In an embodiment, the first chip pad 130 may be a portion of the first wiring pattern 124 exposed from (or with respect to) the first insulating pattern 122 of the first wiring layer 120, unlike the one shown in FIG. 2.

In another embodiment, the first chip pad 130 may not be a portion of the first wiring pattern 124, and may be a separate pad disposed on the first insulating pattern 122 of the first wiring layer 120 and connected to the first wiring pattern 124, as shown in FIG. 2.

The first chip pad 130 may be coplanar with the lower surface of the first wiring layer 120 and/or may protrude above (or formed on) the lower surface of the first wiring layer 120. However, an embodiment of the inventive concept is not limited thereto. For example, the first chip pad 130 may be coplanar with the lower surface of the first wiring layer 120 and/or exposed on (or with respect to) the lower surface of the first wiring layer 120.

The first chip pad 130 may include a conductive material. For example, the first chip pad 130 may include copper (Cu). A first insulating layer 132 may be provided on the lower surface of the first wiring layer 120. The first insulating layer 132 may cover the lower surface of the first wiring layer 120. The first insulating layer 132 may surround the first chip pad 130 on the first wiring layer 120. The first chip pad 130 may be exposed on (or with respect to) a lower surface of the first insulating layer 132. The first insulating layer 132 may include an insulating material. For example, the first insulating layer 132 may include silicon oxide (SiOx), silicon nitride (SiNx), and the like.

A first chip connection terminal 140 may be provided on a lower surface of the first chip pad 130. The first chip connection terminal 140 may include a solder ball or a solder bump. The first chip pad 130 and the first chip connection terminal 140 may be provided in plurality.

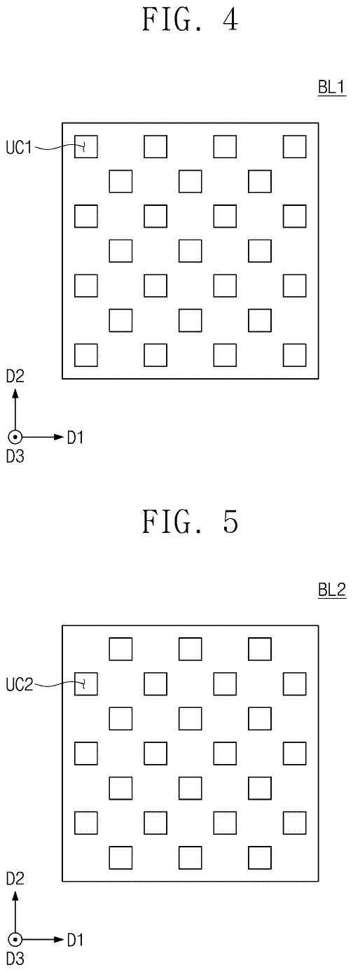

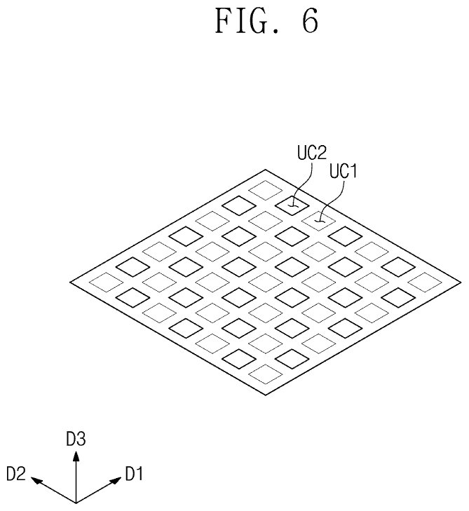

FIG. 3 is an exploded perspective view for describing a buffer layer of a semiconductor package according to embodiments of the inventive concept. FIG. 4 is a plan view for describing a first buffer layer BL1 of a semiconductor package according to embodiments of the inventive concept. FIG. 5 is a plan view for describing a second buffer layer BL2 of a semiconductor package according to embodiments of the inventive concept. FIG. 6 is a perspective view for describing a portion of a semiconductor package according to embodiments of the inventive concept, and illustrates only the first buffer layer BL1 and the second buffer layer BL2 for convenience.

Referring to FIGS. 3 to 6, the buffer layer MBL may include the first buffer layer BL1, the second buffer layer BL2, a third buffer layer BL3, a fourth buffer layer BL4, and a fifth buffer layer BL5. The first buffer layer BL1 may have a lattice structure. The first buffer layer BL1 may include a structure in which a plurality of first unit lattices UC1 are arranged so as to be spaced a certain distance (a predetermined distance) apart. The first unit lattices UC1 may be arranged in a first direction D1 and a second direction D2. The first unit lattices UC1 may be arranged in a plurality of columns and a plurality of rows. In FIG. 6, to clearly show the comparison between the first buffer layer BL1 and the second buffer layer BL2, it is illustrated as if the two layers were on the same plane.

For example, the first unit lattices UC1 may be arranged in at least two columns extending in the first direction D1. The columns of the first unit lattices UC1 may be spaced apart from each other in the second direction D2. In two adjacent columns, the first unit lattices UC1 may be arranged in a zigzag form. In a square formed with four first unit lattices UC1 among the first unit lattices UC1, another first unit lattice UC1 may be disposed in a center of the square. Four first unit lattices UC1 adjacent to each other among the first unit lattices UC1 may form a rhombus shape. In any one of the columns, a distance between two first unit lattices UC1 adjacent to each other may be 9 μm to 30 μm. The distance between the two first unit lattices UC1 adjacent to each other may be constant. Here, the first unit lattices UC1 may represent holes penetrating the first buffer layer BL1. The first unit lattices UC1 may each completely penetrate the first buffer layer BL1.

For example, the lattice structure may be a staggered pattern including a ductile material, and a plurality of holes (first unit lattices UC1) may be arranged in a two-dimensional grid pattern, with the holes organized into multiple rows and columns. The arrangement may follow an alternating pattern, such that in a group of five holes forming a square in a plan view, one of the five holes is positioned in the center of the square, when the five holes are placed adjacent to one another. Additionally, adjacent four holes may form a diamond or rhombus shape in a plan view. Each of the plurality of holes (first unit lattices UC1) may have a quadrilateral shape in a plan view.

Although FIGS. 3 to 6 illustrate the first unit lattices UC1 of the first buffer layer BL1 as having a grid shape with respect to a 45° direction of the first direction D1, an embodiment of the inventive concept is not limited thereto. The first unit lattices UC1 may be spaced apart from each other on the first buffer layer BL1 and arranged in the first direction D1 and the second direction D2 so as to form various shapes. For example, three first unit lattices UC1 adjacent to each other among the first unit lattices UC1 may form an equilateral triangle.

A plane shape (shape viewed from a vertical direction, e.g., the third direction D3) of the first unit lattices UC1 may be quadrilateral. For example, a width of each of the first unit lattices UC1 may be 3 μm to 10 μm, and a height of each of the first unit lattices UC1 may be 3 μm to 10 μm. However, an embodiment of the inventive concept is not limited thereto, and the plane shape of the first unit lattices UC1 may be circular or polygonal. Here, a width of the first unit lattices UC1 may be 3 μm to 10 μm.

A thickness of the first buffer layer BL1 in the third direction D3 may be 1 μm to 2 μm, but an embodiment of the inventive concept is not limited thereto. A material forming the first buffer layer BL1 may have ductility. An elastic modulus of the first buffer layer BL1 may be smaller than an elastic modulus of the first semiconductor substrate 110. A toughness of the first buffer layer BL1 may be larger than a toughness of the first semiconductor substrate 110. For example, the first buffer layer BL1 may include an insulating material. The first buffer layer BL1 may include an insulating polymer. The first buffer layer BL1 may include polyimide.

The second buffer layer BL2 may be provided on an upper surface of the first buffer layer BL1. The second buffer layer BL2 may have a lattice structure. In detail, the second buffer layer BL2 may include a structure in which second unit lattices UC2 are arranged so as to be spaced a certain distance (a predetermined distance) apart. The second unit lattices UC2 may be arranged in the first direction D1 and the second direction D2. The second unit lattices UC2 may be arranged in a plurality of columns and a plurality of rows. For example, the second unit lattices UC2 may be arranged in at least two columns extending in the first direction D1. The columns of the second unit lattices UC2 may be spaced apart from each other in the second direction D2. In two adjacent columns, the second unit lattices UC2 may be arranged in a zigzag form. In a square formed with four second unit lattices UC2 among the second unit lattices UC2, another second unit lattice UC2 may be disposed in a center of the square. Four second unit lattices UC2 adjacent to each other among the second unit lattices UC2 may form a rhombus shape. In any one column, a distance between two second unit lattices UC2 adjacent to each other may be 9 μm to 30 μm. The distance between the two second unit lattices UC2 adjacent to each other may be constant. Here, the second unit lattices UC2 may represent holes penetrating the second buffer layer BL2. The second unit lattices UC2 may each completely penetrate the second buffer layer BL2. The second unit lattices UC2 may be disposed at a different height level than the first unit lattices UC1. For example, the second unit lattices UC2 may be disposed at a higher height level than the first unit lattices UC1 Although FIGS. 3 to 6 illustrate the second unit lattices UC2 of the second buffer layer BL2 as having a grid shape with respect to a 45° direction of the first direction D1, an embodiment of the inventive concept is not limited thereto. The second unit lattices UC2 may be spaced apart from each other on the second buffer layer BL2 and arranged in the first direction D1 and the second direction D2 so as to form various shapes. For example, three second unit lattices UC2 adjacent to each other among the second unit lattices UC2 may form an equilateral triangle. The following descriptions are provided on the basis of the embodiment of FIGS. 3 to 6.

A plane shape of the second unit lattices UC2 may be quadrilateral. For example, a width of each of the second unit lattices UC2 may be 3 μm to 10 μm, and a height of each of the second unit lattices UC2 may be 3 μm to 10 μm. The plane shape of the second unit lattices UC2 may be the same as the plane shape of the first unit lattices UC1. However, an embodiment of the inventive concept is not limited thereto. The plane shape of the second unit lattices UC2 may be different from the plane shape of the first unit lattices UC1, and may be circular or polygonal. Here, a width of the second unit lattices UC2 may be 3 μm to 10 μm.

A thickness of the second buffer layer BL2 in the third direction D3 may be 1 μm to 2 μm, but an embodiment of the inventive concept is not limited thereto. A material forming the second buffer layer BL2 may have ductility. An elastic modulus of the second buffer layer BL2 may be smaller than an elastic modulus of the first semiconductor substrate 110. A toughness of the second buffer layer BL2 may be larger than a toughness of the first semiconductor substrate 110. For example, the second buffer layer BL2 may include an insulating material. The second buffer layer BL2 may include an insulating polymer. The second buffer layer BL2 may include polyimide. The material forming the second buffer layer BL2 may be the same as the material forming the first buffer layer BL1, but an embodiment of the inventive concept is not limited thereto.

In a plan view, the first unit lattices UC1 may be located between the second unit lattices UC2. Hereinafter, arrangement of the first unit lattices UC1 and the second unit lattices UC2 in a plan view will be described. For example, as shown in FIG. 6, the first unit lattices UC1 and the second unit lattices UC2 may be spaced a certain (a predetermined distance) distance apart and alternately arranged along an arbitrary direction (e.g., the first direction D1 or second direction D2) on a plane. The first unit lattices UC1 and the second unit lattices UC2 may form a composite a lattice structure. For example, the first unit lattices UC1 and the second unit lattices UC2 together may form a two-dimensional matrix arrangement (or a two-dimensional array of the unit lattices) in a plan view. Hereinafter, for convenience, the lattice structure formed by the first unit lattices (first holes) UC1 and the second unit lattices (second holes) UC2 may be referred to as a buffer pattern in the buffer layer MBL, such that the arrangement of the first holes UC1 and the second holes UC2 may be a buffer pattern of the buffer layer MLB.

Referring to FIG. 6, the second unit lattices UC2 may not vertically overlap the first unit lattices UC1. In a plan view, the first unit lattices UC1 may be arranged alternately with the second unit lattices UC2 along an arbitrary direction (e.g., the first direction D1 or second direction D2) on a plane such as illustrated in FIG. 6. In a plan view, a distance between the first unit lattice UC1 and the second unit lattice UC2 adjacent to each other may be uniform. Each of the first unit lattices UC1 may be disposed between two adjacent second unit lattices UC2. Four adjacent second unit lattices UC2 may form a quadrangle. The first unit lattices UC1 may be located between four adjacent second unit lattices UC2. In detail, any one of the first unit lattices UC1 may be disposed in the quadrangle. However, an embodiment of the inventive concept is not limited thereto, and a shape of the buffer pattern in a plan view may be various according to arrangement of the first unit lattices UC1 and the second unit lattices UC2. For example, the buffer pattern may form a honeycomb shape or other various shapes. Alternatively, according to other embodiments, three adjacent first unit lattices UC1 among the first unit lattices UC1 may form an equilateral triangle, and three adjacent second unit lattices UC2 among the second unit lattices UC2 may form an equilateral triangle. The first unit lattices UC1 may each be located between the three adjacent second unit lattices UC2.

The third buffer layer BL3 may be interposed between the first buffer layer BL1 and the second buffer layer BL2. An upper surface of the third buffer layer BL3 may be in contact with a lower surface of the second buffer layer BL2. A lower surface of the third buffer layer BL3 may be in contact with an upper surface of the first buffer layer BL1. The third buffer layer BL3 may cover the upper surface of the first buffer layer BL1. The first unit lattices (holes) UC1 of the first buffer layer BL1 may be vertically spaced apart from the second unit lattices (holes) UC2 of the second buffer layer BL2 due to the third buffer layer BL3. The third buffer layer BL3 may not have through-holes penetrating the inside thereof. The upper surface and lower surface of the third buffer layer BL3 may be substantially flat. A thickness of the third buffer layer BL3 in the third direction D3 may be 1 μm to 2 μm, but an embodiment of the inventive concept is not limited thereto. For example, the upper surface of the first buffer layer BL1 may be vertically spaced apart from the lower surface of the second buffer layer BL2. A separation distance between the lower surface of the second buffer layer BL2 and the upper surface of the first buffer layer BL1 may be 1 μm to 2 μm.

A material forming the third buffer layer BL3 may have ductility. An elastic modulus of the third buffer layer BL3 may be smaller than an elastic modulus of the first semiconductor substrate 110. A toughness of the third buffer layer BL3 may be larger than a toughness of the first semiconductor substrate 110. The third buffer material BL3 may include an insulating material. For example, the third buffer layer BL3 may include an insulating polymer. The third buffer layer BL3 may include polyimide. The material forming the third buffer layer BL3 may be the same as the material forming the first buffer layer BL1 and the material forming the second buffer layer BL2, but an embodiment of the inventive concept is not limited thereto.

Although FIG. 3 illustrates the first buffer layer BL1, the second buffer layer BL2, and the third buffer layer BL3 as separate elements having boundary surfaces therebetween, an embodiment of the inventive concept is not limited thereto. For example, the first buffer layer BL1, the second buffer layer BL2, and the third buffer layer BL3 may form a single continuous body formed of the same material without a boundary interface therebetween. The boundary surfaces between the first buffer layer BL1, the second buffer layer BL2, and the third buffer layer BL3 may be invisible.

For example, the buffer layer MBL may be provided as a single homogenous layer including first holes and second holes spaced apart from each other. In these cases, the plane shown in FIG. 6 may represent the single layer. The first holes (or recesses) may be recessed from a lower surface of the single layer towards the inside (or interior) of the single layer. The second holes (or recesses) may be recessed from an upper surface of the single layer towards the inside of the single layer. Here, the first holes may correspond to the first unit lattices UC1, and the second holes may correspond to the second unit lattices UC2. For example, the first holes may each be disposed between two adjacent second holes among the second holes, in a plan view. The first holes and the second holes may not completely penetrate the single layer. A height level of a bottom surface of the first holes may be lower than a height level of a bottom surface of the second holes. A distance between the bottom surface of the first holes and the bottom surface of the second holes may be 1 μm to 2 μm.

The recess may allow space in the semiconductor chip. For example, the first and second recesses may be indentations or cavities formed on the upper and lower surfaces of the single homogenous layer. The first and second holes may provide empty spaces (or voids or air gaps) formed by the combination of the recesses and other components to be formed on the upper and lower surfaces of the single homogenous layer. The voids may be the spaces that exist between the recesses and the other components. In an example, the voids may be formed by a combination of the single layer and one of the first semiconductor substrate 110, the first interlayer insulating layer 112, the first wiring layer 120 and an element layer PEL (which is described later).

In another example, the voids may be formed by a combination of a layer (which is formed of a ductile material and has recesses formed on the upper and lower surfaces of the layer) and another layer (such as the third to fifth buffer layers BL3 BL4 and BL5) thereby forming the buffer layer MBL.

The fourth buffer layer BL4 may be provided on a lower surface of the first buffer layer BL1. The fourth buffer layer BL4 may cover the lower surface of the first buffer layer BL1. A thickness of the fourth buffer layer BL4 in the third direction D3 may be 1 μm to 2 μm, but an embodiment of the inventive concept is not limited thereto. The fourth buffer layer BL4 may not have through-holes penetrating the inside thereof. An upper surface and lower surface of the fourth buffer layer BL4 may be substantially flat.

The fifth buffer layer BL5 may be provided on an upper surface of the second buffer layer BL2. The fifth buffer layer BL5 may cover the upper surface of the second buffer layer BL2. A thickness of the fifth buffer layer BL5 in the third direction D3 may be 1 μm to 2 μm, but an embodiment of the inventive concept is not limited thereto. The fifth buffer layer BL5 may not have through-holes penetrating the inside thereof. An upper surface and lower surface of the fifth buffer layer BL5 may be substantially flat.

Materials forming the fourth buffer layer BL4 and the fifth buffer layer BL5 may have ductility. Elastic modulus of the fourth buffer layer BL4 and the fifth buffer layer BL5 may be smaller than an elastic modulus of the first semiconductor substrate 110. Toughness of each of the fourth buffer layer BL4 and the fifth buffer layer BL5 may be larger than a toughness of the first semiconductor substrate 110. The fourth buffer layer BL4 and the fifth buffer layer BL5 may include an insulating material. For example, the fourth buffer layer BL4 and the fifth buffer layer BL5 may include an insulating polymer. The fourth buffer layer BL4 and the fifth buffer layer BL5 may include polyimide. The material forming the fourth buffer layer BL4 may be the same as the material forming the fifth buffer layer BL5, but an embodiment of the inventive concept is not limited thereto.

The buffer pattern of the buffer layer MBL may function as a structural vulnerability point. For example, the buffer pattern may help improve the structural vulnerabilities of the semiconductor package (or first semiconductor chip 100). The buffer pattern may help address structural weaknesses that may arise during the manufacturing process of the semiconductor package (or first semiconductor chip 100). When external stress is applied to the semiconductor package, the stress may be concentrated on the buffer pattern of the buffer layer MBL. The stress may not be delivered (transmitted) to other layers in the first semiconductor chip 100 or the first semiconductor substrate 110 having a high brittleness. The stress may be dispersed (or absorbed) in the buffer layer MBL. Since the buffer pattern is configured with the first unit lattices UC1 and the second unit lattices UC2 alternately arranged, the stress may be delivered along the first unit lattices UC1 and the second unit lattices UC2. A delivery path (or transmission path) of the stress may be increased by the first unit lattices UC1 and the second unit lattices UC2. Accordingly, resistance to a crack that may occur due to the stress may increase. That is, a semiconductor package having improved mechanical characteristics may be provided.

Although FIGS. 1 to 6 illustrate the buffer layer MBL as including the first buffer layer BL1 to the fifth buffer layer BL5, an embodiment of the inventive concept is not limited thereto. The number of layers constituting the buffer layer MBL may be changed as necessary. The buffer layer MBL may include at least one layer among the first to fifth buffer layers BL1 to BL5. For example, the buffer layer MBL may include either the first buffer layer BL1 or the second buffer layer BL2. For another example, the buffer layer MBL may be configured with three layers (i.e., the first buffer layer BL1, the second buffer layer BL2, and the third buffer layer BL3), and may not include the fourth buffer layer BL4 and the fifth buffer layer BL5.

In some embodiments, the buffer layer MBL may be configured with more than five layers as necessary. For example, although not illustrated, a sixth buffer layer may be provided between the fourth buffer layer BL4 and the fifth buffer layer BL5. For example, the sixth buffer layer may be provided on the lower surface of the first buffer layer BL1. The sixth buffer layer may have third unit lattices penetrating the sixth buffer layer. The third unit lattices may form various shapes including a grid shape similarly to the first unit lattices UC1 of the first buffer layer BL1. For example, three third unit lattices adjacent to each other among the third unit lattices may form an equilateral triangle.

The third unit lattices may form a composite buffer pattern together with the first unit lattices UC1 and the second unit lattices UC2. For example, the buffer pattern may have a honeycomb shape. A seventh buffer layer may be provided between the sixth buffer layer and the first buffer layer BL1 as necessary. The seventh buffer layer may not have through-holes penetrating the inside thereof. An upper surface and lower surface of the seventh buffer layer may be substantially flat. The following descriptions are provided on the basis of the embodiment of FIGS. 3 to 6.

Although FIGS. 3 to 6 illustrate the first buffer layer BL1 and the second buffer layer BL2 as having a lattice structure over an entire region, an embodiment of the inventive concept is not limited thereto. The buffer pattern of the buffer layer MBL may be partially provided. For example, the buffer pattern of the buffer layer MBL may be provided in a region of the buffer layer MBL, and may not be provided in another region. The buffer pattern of the buffer layer MBL may be provided to (or in) a partial region of the buffer layer MBL. In detail, the first unit lattices UC1 of the first buffer layer BL1 may be provided to a first region of the first buffer layer BL1. The first region may represent any partial region of the first buffer layer BL1 in a plan view. The second unit lattices UC2 of the second buffer layer BL2 may be provided to a second region of the second buffer layer BL2. In a plan view, the second unit lattices UC2 in the second region may be arranged alternately with the first unit lattices UC1 in the first region so as to constitute a buffer pattern. The buffer pattern in the partial region of the buffer layer MBL may be disposed spaced apart from the connection via penetrating the buffer layer MBL. Accordingly, the first unit lattices UC1 and the second unit lattices UC2 may not hinder an electrical connection between the first wiring pattern 124 and the integrated element or the integrated circuits.

In addition, although FIGS. 1 and 2 illustrate the buffer layer MBL as being provided between the first interlayer insulating layer 112 and the first wiring layer 120, an embodiment of the inventive concept is not limited thereto. The buffer layer MBL may be interposed between the first semiconductor substrate 110 and the first insulating layer 132. For example, the buffer layer MBL may be provided between any two layers between a lower surface of the first semiconductor substrate 110 and an upper surface of the first insulating layer 132. For example, the buffer layer MBL may be provided between the first semiconductor substrate 110 and the first interlayer insulating layer 112. For another example, the buffer layer MBL may be provided between the first wiring layer 120 and the first insulating layer 132. Here, similarly to the above descriptions, the buffer pattern of the buffer layer MBL may be provided to (or in) a partial region of the buffer layer MBL so as not to hinder an electrical connection between the first wiring pattern 124 and the integrated element or the integrated circuits.

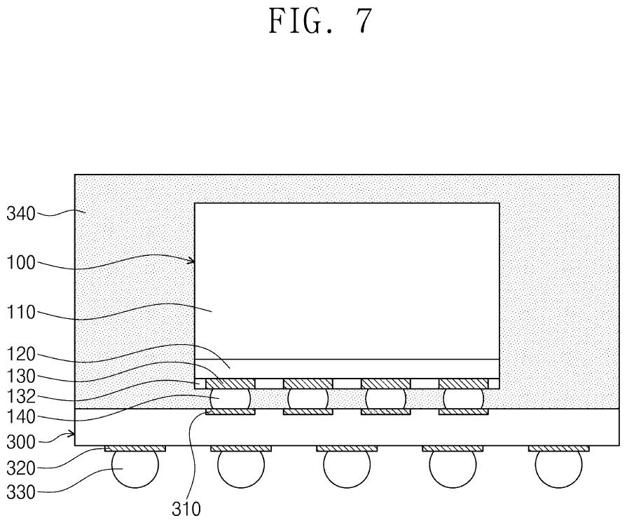

FIG. 7 is a cross-sectional view for describing a semiconductor package according to embodiments of the inventive concept. Referring to FIG. 7, a package substrate 300, the first semiconductor chip 100, and a molding layer 340 may be provided. The package substrate 300 may be a redistribution substrate. For example, although not illustrated, the package substrate 300 may include a single substrate wiring layer or two or more substrate wiring layers stacked on each other. In the present disclosure, a substrate wiring layer may refer to a wiring layer formed by patterning each of an insulating material layer and a conductive material layer. Each of the substrate wiring layers may include an insulating pattern and a conductive pattern in the insulating pattern. The conductive pattern of any one of the substrate wiring layers may be connected to the conductive pattern of another adjacent substrate wiring layer.

The package substrate 300 may have an upper substrate pad 310. The upper substrate pad 310 may be an upper portion of the conductive pattern of an uppermost substrate wiring layer among the substrate wiring layers or may be separate pads electrically connected to the conductive pattern in the substrate wiring layer. The upper substrate pad 310 may be disposed on an upper surface of the package substrate 300. The upper substrate pad 310 may be coplanar with the upper surface of the package substrate 300 and exposed on the package substrate 300. However, an embodiment of the inventive concept is not limited thereto, and the upper substrate pad 310 may protrude above the upper surface of the package substrate 300. The upper substrate pad 310 may be provided in plurality.

Although FIG. 7 illustrates the package substrate 300 as a redistribution substrate, an embodiment of the inventive concept is not limited thereto. According to other embodiments, the package substrate 300 may be a printed circuit board (PCB). Here, the package substrate 300 may have an internal wiring pattern provided in the package substrate 300. For example, the package substrate 300 may have a structure in which an insulating pattern and an internal wiring pattern are alternately stacked. Here, the upper substrate pad 310 may be a separate pad electrically connected to the internal wiring pattern or a portion of the internal wiring pattern protruding above the upper surface of the package substrate 300. Hereinafter, descriptions will be continuously provided with respect to the embodiment of FIG. 7.

A lower substrate pad 320 and a substrate connection terminal 330 may be provided on a lower surface of the package substrate 300. The lower substrate pad 320 may be a separate pad disposed on the lower surface of the package substrate 300 and connected to the conductive pattern of the package substrate 300 or may be a portion of the conductive pattern exposed on the lower surface of the package substrate 300. However, an embodiment of the inventive concept is not limited thereto, and the lower substrate pad 320 may protrude above the lower surface of the package substrate 300. The substrate connection terminal 330 may include a solder ball, a solder bump, or the like. The lower substrate pad 320 and the substrate connection terminal 330 may be provided in plurality. The substrate connection terminals 330 may each be disposed on a lower surface of each of the corresponding lower substrate pads 320.

The first semiconductor chip 100 may be provided on the upper surface of the package substrate 300. Here, the first semiconductor chip 100 may be the same as or similar to the first semiconductor chip 100 described above with reference to FIGS. 1 and 2. The first semiconductor chip 100 may be mounted on the package substrate 300 through the first chip connection terminal 140. For example, the first semiconductor chip 100 may be flip-chip bonded to the package substrate 300. One end of the first chip connection terminal 140 may be in contact with the first chip pad 130. The other end of the first chip connection terminal 140 may be in contact with the upper substrate pad 310 of the package substrate 300. The first chip connection terminal 140 may be electrically connected to the upper substrate pad 310 through the first chip pad 130.

Although FIG. 7 illustrates that the first semiconductor chip 100 includes the first chip connection terminal 140 and is mounted on the package substrate 300 through the first chip connection terminal 140, an embodiment of the inventive concept is not limited thereto. For example, the first semiconductor chip 100 may not include the first chip connection terminal 140. The first semiconductor chip 100 may be mounted on the package substrate 300 through wire bonding. In detail, the first semiconductor chip 100 may include a connection pad provided on an upper surface of the first semiconductor chip 100. The first semiconductor chip 100 may be electrically connected to the package substrate 300 by a wire extending from the connection pad to the upper substrate pad 310 of the package substrate 300.

Throughout the specification, like features and elements have been identified by the same or similar reference numerals and/or letters, and, repetitive descriptions may be omitted. In describing each embodiment, previously discussed content may be briefly explained or omitted for conciseness. However, such repetition in the reference numerals and/or letters may not be limiting the present invention, and does not in itself dictate a relationship between the various embodiments and/or configurations discussed.

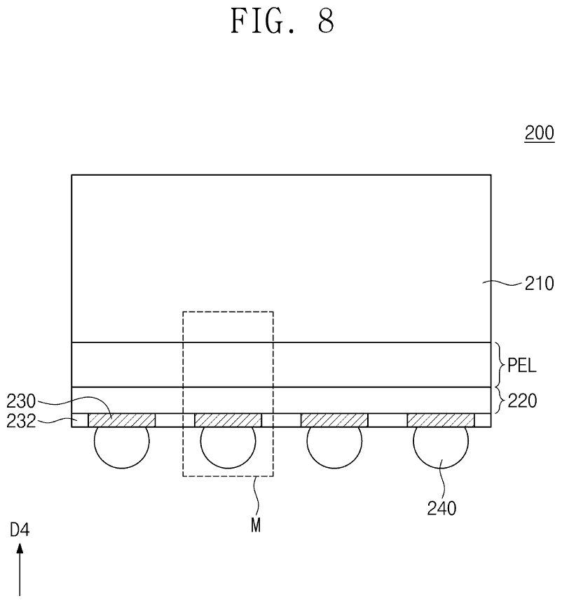

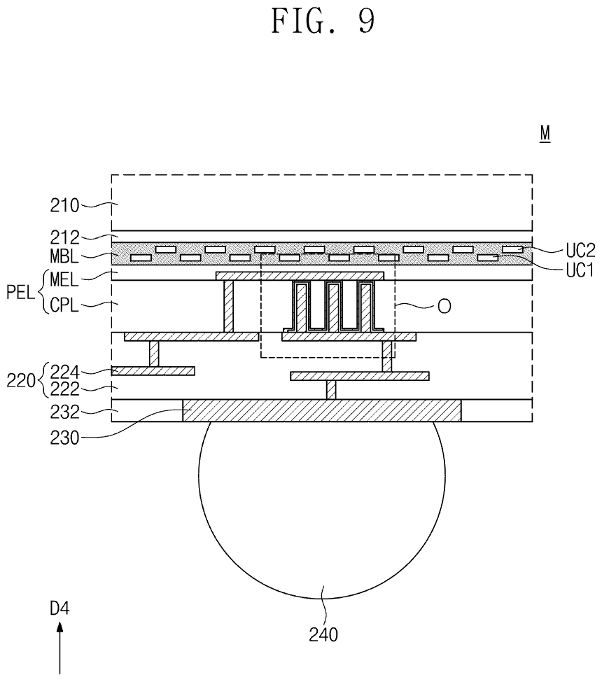

FIG. 8 is a cross-sectional view for describing a semiconductor package according to embodiments of the inventive concept. FIG. 9 is an enlarged view of a portion, which is the portion M of FIG. 8, of a semiconductor package according to embodiments of the inventive concept. Referring to FIGS. 8 and 9, a second semiconductor chip 200 may be provided. The second semiconductor chip 200 may include a second semiconductor substrate 210 and an element layer PEL on a lower surface of the second semiconductor substrate 210. The second semiconductor substrate 210 may include a semiconductor material. For example, the second semiconductor substrate 210 may include silicon (Si). A second interlayer insulating layer 212 may be provided on a lower surface of the second semiconductor substrate 210. The second interlayer insulating layer 212 may cover the lower surface of the second semiconductor substrate 210. The second interlayer insulating layer 212 may include a multi-layer including at least one of silicon oxide, silicon nitride, or silicon oxynitride. However, an embodiment of the inventive concept is not limited thereto.

Referring to FIG. 9, the buffer layer MBL may be provided on a lower surface of the second interlayer insulating layer 212 (in FIG. 8, the buffer layer MBL and the second interlayer insulating layer 212 are not shown to improve the understanding of the drawing). The buffer layer MBL may cover the lower surface of the second interlayer insulating layer 212. The buffer layer MBL may be substantially the same as described above with reference to FIGS. 1 to 6. The buffer layer MBL may have at least one layer. The buffer layer MBL may include a buffer pattern. A thickness of the buffer layer MBL in a fourth direction D4 may be 5 μm to 10 μm. Here, the fourth direction D4 may represent a direction perpendicular to an upper surface of the second semiconductor chip 200.

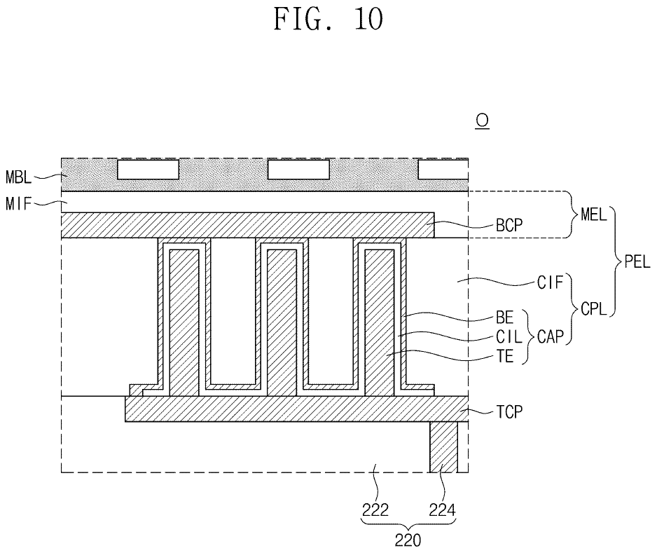

The element layer PEL may be provided on a lower surface of the buffer layer MBL. The element layer PEL may include a conductive layer (e.g., metal layer) MEL and a passive element layer (capacitor layer) CPL on a lower surface of the metal layer MEL. The element layer PEL may include at least one passive element (or passive device). In detail, the capacitor layer CPL may include at least one capacitor element CAP. The capacitor element CAP may include various types of capacitors. For example, the capacitor element CAP may include (or be) a multilayer ceramic capacitor (MLCC), a tantalum capacitor, a film capacitor, a deep trench capacitor (DTC), or an integrated stacked capacitor (ISC). The capacitor element CAP may representatively include an ISC. Hereinafter, for convenience, the capacitor element CAP of the second semiconductor chip 200 is assumed to include an ISC. Structures of the metal layer MEL and the ISC will be described in more detail with reference to FIG. 10.

A second wiring layer 220 may be provided on a lower surface of the element layer PEL. The second wiring layer 220 may have a second insulating pattern 222 and a second wiring pattern 224 provided in the second insulating pattern 222. The second insulating pattern 222 may cover the lower surface of the element layer PEL. The second wiring pattern 224 may be in contact with or electrically connected to the capacitor element CAP of the element layer PEL.

A second chip connection pad 230 may be provided on the lower surface of the second semiconductor substrate 210. The second chip connection pad 230 may be a portion of the second wiring pattern 224 exposed from the second insulating pattern 222 of the second wiring layer 220 or may be a separate pad disposed on the second insulating pattern 222 of the second wiring layer 220 and connected to the second wiring pattern 224. The second chip connection pad 230 may be coplanar with the lower surface of the second wiring layer 220 and may protrude above the lower surface of the second wiring layer 220. However, an embodiment of the inventive concept is not limited thereto, and the second chip connection pad 230 may be coplanar with the lower surface of the second wiring layer 220 and exposed on the lower surface of the second wiring layer 220. The second chip connection pad 230 may include a conductive material. For example, the second chip connection pad 230 may include copper (Cu). A second insulating layer 232 may be provided on the lower surface of the second wiring layer 220. The second insulating layer 232 may cover the lower surface of the second wiring layer 220. The second insulating layer 232 may surround the second chip connection pad 230 on the second wiring layer 220. The second chip connection pad 230 may be exposed on a lower surface of the second insulating layer 232. The second insulating layer 232 may include an insulating material. For example, the second insulating layer 232 may include silicon oxide (SiOx), silicon nitride (SiNx), and the like.

A second chip connection terminal 240 may be provided on a lower surface of the second chip connection pad 230. The second chip connection terminal 240 may include a solder ball or a solder bump. The second chip connection pad 230 and the second chip connection terminal 240 may be provided in plurality.

Although FIG. 9 illustrates the buffer layer MBL as having a lattice structure over an entire region, an embodiment of the inventive concept is not limited thereto. The buffer pattern of the buffer layer MBL may be partially provided. For example, the buffer pattern of the buffer layer MBL may be provided in a region of the buffer layer MBL, and may not be provided in another region. The buffer pattern of the buffer layer MBL may be provided to a partial region of the buffer layer MBL. The buffer pattern may be provided in structurally vulnerable regions and/or a region in which the capacitor element CAP is provided in the second semiconductor chip 200. For example, the buffer pattern may be provided to a region on an upper surface of the capacitor element CAP. The buffer pattern may at least partially overlap the capacitor element CAP in a plan view.

FIG. 10 is an enlarged view of a portion, which is the portion O of FIG. 9, of a semiconductor package according to embodiments of the inventive concept. Referring to FIGS. 9 and 10, the capacitor layer CPL may include a capacitor insulating layer CIF and the capacitor element CAP. The capacitor element CAP may be provided in the capacitor insulating layer CIF. The capacitor insulating layer CIF may include an insulating material. For example, the capacitor insulating layer CIF may include a silicon-based insulating material such as tetraethyl orthosilicate, silicon oxide, silicon carbide, and/or silicon nitride. The capacitor element CAP may be a capacitor including a lower electrode BE, an upper electrode TE, and a capacitor dielectric layer CIL. A thickness of the capacitor layer CPL in the fourth direction D4 may be 5 μm to 15 μm, but an embodiment of the inventive concept is not limited thereto.

An upper electrode pad TCP may be provided on a lower surface of the capacitor layer CPL. Although FIG. 9 illustrates the upper electrode pad TCP as protruding above the upper surface of the capacitor layer CPL, an embodiment of the inventive concept is not limited thereto. The upper electrode pad TCP may be coplanar with the lower surface of the capacitor layer CPL and protrude above the lower surface of the capacitor layer CPL. The upper electrode pad TCP may have a plate shape. The capacitor element CAP may be provided on an upper surface of the upper electrode pad TCP. The capacitor element CAP may be in contact with the upper electrode pad TCP. The upper electrode pad TCP may be connected to a portion of the second wiring pattern 224. For example, the capacitor element CAP may be electrically connected to the second wiring pattern 224 through the upper electrode pad TCP.

The capacitor element CAP may include the lower electrode BE, the upper electrode TE, and the capacitor dielectric layer CIL between the lower electrode BE and the upper electrode TE. The upper electrode TE may be provided in plurality. The plurality of upper electrodes TE may have a pillar shape perpendicularly extending from the upper electrode pad TCP. The upper electrodes TE may have a uniform width and height. Lower surfaces of the upper electrodes TE may be substantially coplanar. The upper electrodes TE may be arranged in various forms. For example, the upper electrodes TE may be spaced apart from each other on the upper surface of the upper electrode pad TCP. Alternatively, the upper electrodes TE may be arranged in a zigzag or honeycomb form in a plan view. Arranging the upper electrodes TE in a zigzag or honeycomb form may be advantageous in increasing a diameter of the upper electrodes TE and may improve the degree of integration of the upper electrodes TE. The upper electrodes TE may be electrically connected in common to the upper electrode pad TCP. The upper electrodes TE may be connected to and in contact with the upper surface of the upper electrode pad TCP. However, an embodiment of the inventive concept is not limited thereto, and the upper electrodes TE may be connected to the upper electrode pad TCP through vias arranged on the lower surfaces of the upper electrodes TE.

The capacitor dielectric layer CIL and the lower electrode BE may be sequentially located on the upper electrodes TE. The capacitor dielectric layer CIL and the lower electrode BE may cover upper surfaces and side surfaces of the upper electrodes TE. The capacitor dielectric layer CIL may be located between the upper electrodes TE and the lower electrode BE. The capacitor dielectric layer CIL may fill a space between the upper electrodes TE and the lower electrode BE while covering the upper electrodes TE with a uniform thickness. In some embodiments, the capacitor dielectric layer CIL may cover upper surfaces and lower surfaces of the upper electrodes TE and at least a portion of an upper surface of the upper electrode pad TCP exposed between the upper electrodes TE with respect to the capacitor dielectric layer CIL. The capacitor dielectric layer CIL may extend from outer side surfaces of the upper electrodes TE to the upper surface of the upper electrode pad TCP and cover at least a portion of the upper electrode pad TCP. A thickness of the capacitor dielectric layer CIL may be smaller than thicknesses of the upper electrodes TE and the lower electrode BE. The capacitor dielectric layer CIL may include a layer selected from metal oxides (such as HfO₂, ZrO₂, Al₂O₃, La₂O₃, Ta₂O₃, and TiO₂) and perovskite-structure piezoelectric materials (such as SrTiO₃(STO), (Ba,Sr)TiO₃(BST), BaTiO₃, PZT, and PLZT), or combinations thereof.

The lower electrode BE may be located on the capacitor dielectric layer CIL. The lower electrode BE may conformally cover the capacitor dielectric layer CIL. Alternatively, the lower electrode BE may fill a space between the upper electrodes TE on the capacitor dielectric layer CIL. When the upper electrodes TE are provided in plurality, a lower electrode BE may cover the plurality of upper electrodes TE. For example, the upper electrodes TE may share one lower electrode BE. The upper electrodes TE and the lower electrode BE may include high-melting point metal layers such as cobalt, titanium, nickel, tungsten, and molybdenum and/or metal nitride layers such as titanium nitride (TiN), titanium silicon nitride (TiSiN), titanium aluminum nitride (TiAIN), tantalum nitride (TaN), tantalum silicon nitride (TaSiN), tantalum aluminum nitride (TaAIN), and tungsten nitride (WN).

A lower electrode pad BCP may be disposed on an upper surface of the lower electrode BE. A lower surface of the lower electrode pad BCP may be in contact with the lower electrode BE. The lower electrode BE may be electrically connected to the lower electrode pad BCP. The lower electrode pad BCP may have a plate shape. The lower electrode pad BCP may include various metal materials such as copper (Cu), aluminum (Al), and/or nickel (Ni).

The metal layer MEL may be provided on an upper surface of the capacitor layer CPL. The metal layer MEL may include a third insulating pattern MIF and the lower electrode pad BCP in the third insulating pattern MIF. The capacitor element CAP may be electrically connected to the lower electrode pad BCP. Although FIG. 9 illustrates the metal layer MEL as including only the third insulating pattern MIF and the lower electrode pad BCP, an embodiment of the inventive concept is not limited thereto. Although not illustrated, the metal layer MEL may further include a third wiring pattern in the third insulating pattern MIF. Here, the lower electrode pad BCP may be a portion of the third wiring pattern exposed from the third insulating pattern MIF. Hereinafter, descriptions will be provided with respect to the embodiment of FIG. 9.

The capacitor layer CPL may further include a through-via. The through-via may penetrate a portion of the second semiconductor chip 200 in the fourth direction D4. For example, the through-via may penetrate the capacitor layer CPL. The through-via may penetrate the capacitor layer CPL and may be connected to the second wiring pattern 224. An upper surface of the through-via may be connected to the lower electrode pad BCP. The through-via may be electrically connected to the capacitor element CAP. For example, the lower electrode BE of the capacitor element CAP may be electrically connected to the second chip connection pad 230 through the lower electrode pad BCP and the through-via. The through-via may include, for example, at least one metal among aluminum (Al), copper (Cu), tungsten (W), molybdenum (Mo), and cobalt (Co).

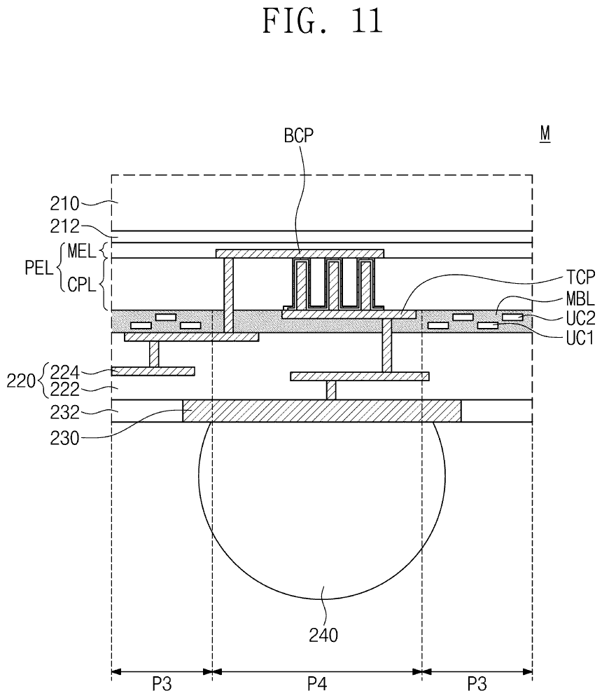

Although FIGS. 9 and 10 illustrate the buffer layer MBL as being provided between the second interlayer insulating layer 212 and the metal layer MEL, an embodiment of the inventive concept is not limited thereto. FIG. 11 is an enlarged view of a portion, which is the portion M of FIG. 8, of a semiconductor package according to embodiments of the inventive concept. Referring to FIG. 11, the buffer layer MBL may be provided between any two layers between a lower surface of the second semiconductor substrate 210 and an upper surface of the second insulating layer 232. For example, the buffer layer MBL may be provided between the element layer PEL and the second wiring layer 220.

A through-via of the capacitor layer CPL may penetrate a portion of the second semiconductor chip 200 in the fourth direction D4. For example, the through-via may extend from the lower electrode pad BCP and penetrate the capacitor layer CPL and the buffer layer MBL. The through-via may penetrate the buffer layer MBL and may be connected to the second wiring pattern 224 of the second wiring layer 220. The upper electrode pad TCP may protrude above a lower surface of the capacitor layer CPL. The upper electrode pad TCP and a portion of the second wiring pattern 224 connected to the upper electrode pad TCP may be provided in the buffer layer MBL.

The buffer pattern of the buffer layer MBL may be provided to a partial region of the buffer layer MBL. In a plan view, the buffer pattern of the buffer layer MBL may be horizontally spaced apart from the through-via, the upper electrode pad TCP, and the second wiring pattern 224 connected to the upper electrode pad TCP. In detail, the buffer layer MBL may include a third region P3 and a fourth region P4 that are different from each other. Here, the fourth region P4 of the buffer layer MBL may represent a region in which the through-via and the upper electrode pad TCP are provided. In the fourth region P4, the second wiring pattern 224 may be connected to the upper electrode pad TCP. The third region P3 may represent the remaining region of the buffer layer MBL other than the fourth region P4. The buffer pattern of the buffer layer MBL may be provided to (or in) the third region P3. The first unit lattices UC1 and the second unit lattices UC2 may constitute the buffer pattern of the buffer layer MBL in the third region P3 of the buffer layer MBL. The third region P3 and the fourth region P4 may be provided in plurality as necessary. Since the buffer pattern is not provided in the fourth region P4, the first unit lattices UC1 and the second unit lattices UC2 may not hinder an electrical connection between the capacitor element CAP and the second wiring pattern 224.

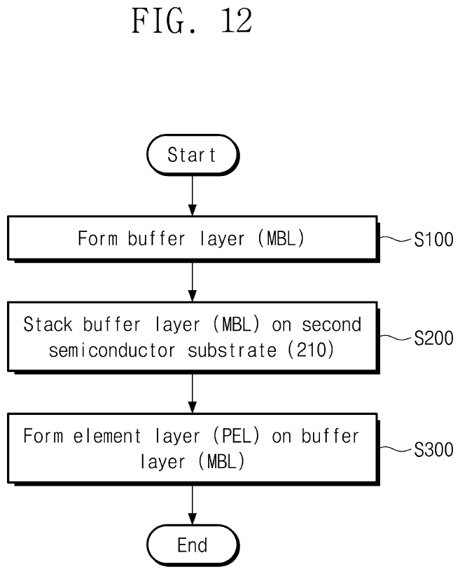

FIG. 12 is a flowchart illustrating a method of manufacturing a semiconductor package according to embodiments of the inventive concept. Referring to FIG. 12, the method of manufacturing a semiconductor package according to an embodiment of the inventive concept may include a first step S100 of forming the buffer layer MBL, a second step S200 of stacking the buffer layer MBL on the second semiconductor substrate 210, and a third step S300 of forming the element layer PEL on the buffer layer MBL. Although the third step S300 is described as a step of forming the element layer PEL on the buffer layer MBL for convenience, the third step S300 may represent a step of completing the semiconductor package of FIG. 8 by forming other components of the second semiconductor chip 200 and the element layer PEL on the buffer layer MBL.

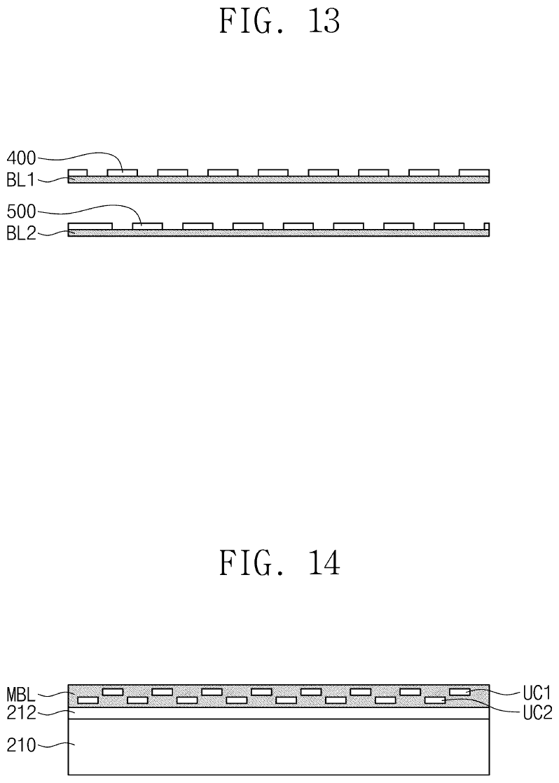

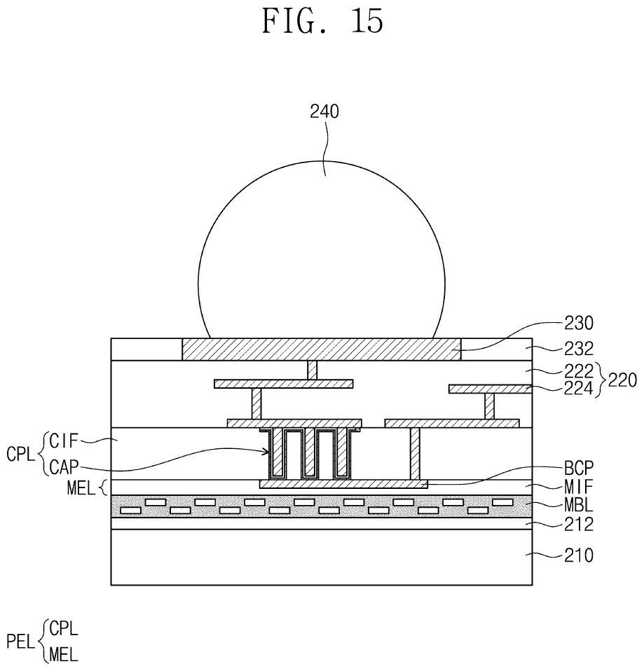

FIG. 13 is a schematic diagram for describing the first step S100 of FIG. 12. FIG. 14 is a schematic diagram for describing the second step S200 of FIG. 12. FIG. 15 is a schematic diagram for describing the third step S300 of FIG. 12. For convenience, some regions are enlarged in FIGS. 14 and 15. Referring to FIG. 13, the first buffer layer BL1 may be provided in the first step S100. A first mask pattern 400 may be formed on the first buffer layer BL1. The first mask pattern 400 may have openings exposing an upper surface of the first buffer layer BL1. The first mask pattern 400 may include first openings located on the first buffer layer BL1. A plane shape and arrangement of the first openings may be the same as or substantially similar to the plane shape and arrangement of the first unit lattices UC1 of the first buffer layer BL1 described above with reference to FIG. 4.

An etching process may be performed on the first buffer layer BL1. At least a portion of the first buffer layer BL1 exposed by the first mask pattern 400 may be etched and removed through the etching process. In detail, the first unit lattices UC1 penetrating the first buffer layer BL1 may be formed. Thereafter, the first mask pattern 400 may be removed. A shape of the first buffer layer BL1 formed through the etching process may be the same as described above with reference to FIG. 4.

The second buffer layer BL2 including the second unit lattices UC2 may be manufactured on the second buffer layer BL2 by performing an etching process as described above. In detail, a second mask pattern 500 may be formed on the second buffer layer BL2. The second mask pattern 500 may have openings exposing an upper surface of the second buffer layer BL2. The second mask pattern 500 may include second openings located on the second buffer layer BL2. A plane shape and arrangement of the second openings may be the same as or substantially similar to the plane shape and arrangement of the second unit lattices UC2 of the second buffer layer BL2 described above with reference to FIG. 5.

An etching process may be performed on the second buffer layer BL2. At least a portion of the second buffer layer BL2 exposed by the second mask pattern 500 may be etched and removed through the etching process. In detail, the second unit lattices UC2 penetrating the second buffer layer BL2 may be formed. Thereafter, the second mask pattern 500 may be removed. A shape of the second buffer layer BL2 formed through the etching process may be the same as described above with reference to FIG. 5.

Thereafter, although not illustrated, the first buffer layer BL1 may be stacked on the fourth buffer layer BL4. The third buffer layer BL3, the second buffer layer BL2, and the fifth buffer layer BL5 may be sequentially stacked on the first buffer layer BL1. Here, the third to fifth buffer layers BL3 to BL5 may be substantially the same as described above with reference to FIGS. 3 to 6, respectively. As described above, the buffer layer MBL of a multi-layer structure may be manufactured.

Referring to FIG. 14, the second semiconductor substrate 210 and the second interlayer insulating layer 212 may be provided in the second step S200. Here, the second semiconductor substrate 210 and the second interlayer insulating layer 212 may be substantially the same as described above with reference to FIGS. 8 and 9. The buffer layer MBL manufactured as described above may be stacked on an upper surface of the second interlayer insulating layer 212.

Referring to FIG. 15, the element layer PEL may be formed on an upper surface of the buffer layer MBL in the third step S300. The element layer PEL may include the metal layer MEL and the capacitor layer CPL. In detail, a third insulating pattern MIF may be formed by depositing an insulating material on the upper surface of the buffer layer MBL. Holes for accommodating the lower electrode pad BCP may be formed by patterning the third insulating pattern MIF. The lower electrode pad BCP filling the holes may be formed on the third insulating pattern MIF. The lower electrode pad BCP may be formed through a plating process. An upper surface of the lower electrode pad BCP may be exposed on (or with respect to) an upper surface of the third insulating pattern MIF.

The capacitor layer CPL may be formed on the metal layer MEL. The capacitor insulating layer CIF may be formed by depositing an insulating material on the metal layer MEL. At least one capacitor element CAP may be formed by a series of processes including patterning of the capacitor insulating layer CIF. The capacitor element CAP may be electrically connected to the exposed lower electrode pad BCP.

The second wiring layer 220 may be formed on the capacitor layer CPL. The second insulating pattern 222 may be formed by depositing an insulating material on an upper surface of the capacitor layer CPL. Holes for accommodating the second wiring pattern 224 may be formed by patterning the second insulating pattern 222. The second wiring pattern 224 filling the holes may be formed on the second insulating pattern 222. An upper surface of a portion of the second wiring pattern 224 may be exposed on an upper surface of the second insulating pattern 222. The second insulating layer 232 may be formed by applying an insulating material on the second insulating pattern 222. Through-holes may be formed by performing an etching process, an exposure process and a development process on the second insulating layer 232. The second chip connection pad 230 may be formed by filling the through-holes of the second insulating layer 232 with a conductive material. The second chip connection pad 230 may be electrically connected to the exposed upper surface of the second wiring pattern 224. A second chip connection terminal 240 may be provided on the second chip connection pad 230. Thereafter, a resultant structure may be turned upside down. As described above, the semiconductor package of FIG. 8 may be manufactured.

Referring to FIGS. 1 to 15 and related description, according to some embodiments, the unit lattices may provide a space for air gaps (or voids) in the semiconductor chips 100 and 200 (or in the semiconductor packages) as described above. The air gap may comprise a gap having air or other gases (e.g., such as those present during manufacturing) or may comprise a gap forming a vacuum therein.

A semiconductor package according to embodiments of the inventive concept may include a buffer layer so as to prevent (or substantially prevent) occurrence of a crack in a semiconductor element due to an impact (e.g., external stress). Therefore, a semiconductor package having improved mechanical characteristics may be provided.

Furthermore, a semiconductor package according to embodiments of the inventive concept may include a buffer layer having a pattern so that an impact applied to a semiconductor element may be guided to (or absorbed by) the buffer layer. Accordingly, the impact may be prevented from diffusing (or transmitting) to other layers that are highly vulnerable in the semiconductor element. That is, the driving stability of the semiconductor package may be improved.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A semiconductor device comprising:
a semiconductor substrate;
an element layer on the semiconductor substrate;
a wiring layer on the element layer; and
a buffer layer provided between the semiconductor substrate and the element layer or between the element layer and the wiring layer,
wherein the buffer layer includes:
a first buffer layer including a plurality of first voids spaced apart from each other, and
a second buffer layer provided on the first buffer layer and including a plurality of second voids spaced apart from each other,
wherein the plurality of second voids are disposed at a different height level than the plurality of first voids,
wherein the plurality of second voids include a plurality of pairs of adjacent second voids, and
wherein, in a plan view, each of the first voids of the buffer layer is disposed between a corresponding one of the plurality of pairs of adjacent second voids.

2. The semiconductor device of claim 1,
wherein the buffer layer further includes:
a third buffer layer interposed between the first buffer layer and the second buffer layer,
a fourth buffer layer provided on a lower surface of the first buffer layer, and
a fifth buffer layer provided on an upper surface of the second buffer layer, and
wherein the first voids are vertically spaced apart from the second voids by the third buffer layer.

3. The semiconductor device of claim 1, wherein:
a width of each of the first voids and the second voids is 3 μm to 10 μm,
a distance between two adjacent second voids among the second voids is uniform, and
a distance between two adjacent first voids among the first voids is uniform.

4. The semiconductor device of claim 1, wherein each of a thickness of the first buffer layer and a thickness of the second buffer layer is 1 μm to 2 μm.

5. The semiconductor device of claim 1, wherein the buffer layer is interposed between the semiconductor substrate and the element layer.

6. The semiconductor device of claim 1,
wherein the element layer includes a capacitor including:
a first electrode,
a capacitor dielectric layer covering the first electrode, and having a uniform thickness, and
a second electrode covering the first electrode on the capacitor dielectric layer.

7. The semiconductor device of claim 1, wherein the buffer layer is interposed between the element layer and the wiring layer.

8. The semiconductor device of claim 7, wherein:
the buffer layer includes a first region and a second region,
the first voids and the second voids constitute a buffer pattern of the buffer layer in the first region,
the buffer layer further includes a through-via penetrating the buffer layer in the second region, and
the through-via electrically connects the element layer and the wiring layer.

9. The semiconductor device of claim 1, wherein:
an upper surface of the first buffer layer is vertically spaced apart from a lower surface of the second buffer layer, and
a separation distance between the lower surface of the second buffer layer and the upper surface of the first buffer layer is 1 μm to 2 μm.

10. The semiconductor device of claim 1, wherein an elastic modulus of the buffer layer is smaller than an elastic modulus of the semiconductor substrate.

11. A semiconductor device comprising:
a semiconductor substrate;
an element layer on the semiconductor substrate;
a wiring layer on the element layer; and
a first buffer layer provided between the semiconductor substrate and the element layer or between the element layer and the wiring layer,
wherein the first buffer layer includes first voids and second voids spaced apart from each other,
wherein each of the first voids is formed by a first recess extending from an upper surface of the first buffer layer towards an inside of the first buffer layer,
wherein each of the second voids is formed by a second recess extending from a lower surface of the first buffer layer towards an inside of the first buffer layer, and
wherein the plurality of second voids include a plurality of pairs of adjacent second voids, and
wherein, in a plan view, each of the first voids of the first buffer layer is disposed between a corresponding one of the plurality of pairs of adjacent second voids.

12. The semiconductor device of claim 11, wherein the first buffer layer includes an insulating polymer.

13. The semiconductor device of claim 11, wherein the first buffer layer is interposed between the semiconductor substrate and the element layer.

14. The semiconductor device of claim 11, wherein:
a height level of bottom surfaces of the first voids is higher than a height level of bottom surfaces of the second voids, and
a distance between the height level of the bottom surfaces of the first voids and the height level of the bottom surfaces of the second voids is 1 μm to 2 μm.

15. The semiconductor device of claim 11, wherein a width of each of the first voids and the second voids is 3 μm to 10 μm.

16. The semiconductor device of claim 11, further comprising: a second buffer layer covering the lower surface of the first buffer layer; and
a third buffer layer covering the upper surface of the first buffer layer,
wherein a lower surface of the second buffer layer and an upper surface of the third buffer layer are flat.

17. The semiconductor device of claim 11, wherein:
the element layer includes a passive device,
the wiring layer includes a connection pad protruding above an upper surface of the wiring layer,
the first buffer layer is interposed between the element layer and the wiring layer,
the passive device is electrically connected to the connection pad through a through-via penetrating the first buffer layer, and
the first voids and the second voids of the first buffer layer are horizontally spaced apart from the through-via in a plan view.

18. A semiconductor device comprising:
a package substrate;
a semiconductor chip disposed on the package substrate; and
a molding layer surrounding the semiconductor chip on the package substrate,
wherein the semiconductor chip includes:
a semiconductor substrate,
a wiring layer on the semiconductor substrate, and
a buffer layer interposed between the semiconductor substrate and the wiring layer,
wherein the buffer layer includes:
a first buffer layer including a plurality of first voids spaced apart from each other, and
a second buffer layer provided on the first buffer layer,
wherein the second buffer layer includes a plurality of second voids spaced apart from each other,
wherein, in a plan view, the first voids and the second voids are alternately arranged, spaced apart from each other by a first distance, and repetitively arranged in a first direction and a second direction that intersect each other, and
wherein an elastic modulus of the buffer layer is smaller than an elastic modulus of the semiconductor substrate.

19. The semiconductor device of claim 18,
wherein the buffer layer further includes a third buffer layer interposed between the first buffer layer and the second buffer layer, and
wherein a thickness of the third buffer layer is 1 μm to 2 μm.

20. The semiconductor device of claim 18,
wherein the semiconductor chip further includes an element layer provided between the semiconductor substrate and the wiring layer,
wherein the element layer further includes a capacitor, and
wherein the capacitor includes:
a first electrode,
a capacitor dielectric layer covering the first electrode with a uniform thickness, and
a second electrode covering the first electrode on the capacitor dielectric layer, and
wherein the buffer layer is interposed between the semiconductor substrate and the element layer.
